(19) United States
(12) Patent Application Publication
(10) Pub. No.: US 2012/0225532 A1
(43) Pub. Date: Sep. 6, 2012

(54) METHOD FOR CONTROLLING A RESISTIVE PROPERTY IN A RESISTIVE ELEMENT USING A GAS CLUSTER ION BEAM

(75) Inventors: John J. Hautala, Beverly, MA (US); Edmund Burke, West Newbury, MA (US)

(73) Assignee: TEL EPION INC., Billerica, MA (US)

(21) Appl. No.: 13/039,965

(22) Filed: Mar. 3, 2011

(51) Int. Cl. H01L 21/02

(52) U.S. Cl. 438/382; 257/E21.004

(57) ABSTRACT

A method for controlling a resistive property or conductive property in a resistive element using a gas cluster ion beam (GCIB) is described. In one embodiment, the method may include controlling a resistive switching behavior in a resistive switching random-access memory device using a gas cluster ion beam (GCIB).

### BACKGROUND OF THE INVENTION

1. Field of Invention

The invention relates to improving a resistive property or conductive property in a resistive element, and more particularly, a method for controlling a resistive switching behavior in a memory device.

2. Description of Related Art

A typical semiconductor memory device utilized during microprocessor operation is a volatile type of memory device. However, in the event of power interruption, the data stored in such a memory device is lost. An alternative to the volatile type of memory device is a non-volatile type memory device. The non-volatile type memory device retains stored information even when power is terminated.

For applications in which a fast memory switching and a high switching endurance is required DRAM (dynamic random access memory) devices of SRAM (static RAM) devices are commonly used. DRAM can support high data transmission rates combined with a relatively small cell size, thus, making it an attractive candidate for commodity products.

Especially for future mobile applications, low power consumption, non-volatility, and high operation speed, enabling fast data rates, are mandatory. Since charge storage memories (e.g., DRAM and floating gate memories like FLASH) are reaching their scaling limits due to data retention problems caused by inevitable charge leakage from the cells, and moreover, poor data sensing capability for the ever decreasing amounts of stored charge, alternative electronic switching mechanisms seem superior to meet the above mentioned requirements.

Therefore, substantive effort is placed in the development of non-volatile memory cells, which are based on fast, scalable, low voltage switching mechanisms including temperature stability and high switching endurance. An emerging area of non-volatile memory cell development is resistive-switching RAM (ReRAM), such as phase-change RAM (PCRAM) or conductive-bridging RAM (CBRAM). ReRAM is based on the manipulation of the resistive switching behavior of a resistive switching layer inserted between a pair of electrodes. However, even with the advancement of ReRAM devices, techniques are sought for altering the resistive switching properties of such layers and improving their manufacture.

### SUMMARY OF THE INVENTION

The invention relates to a method for controlling a resistive property (or conductive property) in a resistive element using a gas cluster ion beam (GCIB). According to one embodiment, the method may include controlling a resistive switching behavior in a non-volatile memory device using a GCIB.

According to another embodiment, a method for preparing a memory device is described. The method includes preparing a resistive switching layer between a pair of electrodes in a non-volatile memory element on a substrate, wherein the resistive switching layer contains a transition metal oxide, a transition metal nitride, a transition metal oxynitride, or a chalcogenide. The method further includes programming a resistive switching property of the resistive switching layer to control a resistive switching behavior of the resistive switching layer using GCIB processing by performing the following: disposing the substrate in a GCIB processing system, producing a GCIB in the GCIB processing system according to a process recipe containing one or more GCIB process parameters selected to achieve the resistive switching property, and exposing the resistive switching layer to the GCIB.

According to another embodiment, a method of preparing a non-volatile memory device is described. The method includes preparing a non-volatile memory device on a substrate, wherein the non-volatile memory device encompasses a resistive-switching random-access memory (ReRAM) device. The method further includes treating at least one layer in the non-volatile memory device using a GCIB to perform at least one of smoothing a surface of the at least one layer, roughening a surface of the at least one layer, etching the at least one layer, growing material on the at least one layer, depositing material on the at least one layer, modifying a composition the at least one layer, amorphizing the at least one layer, or changing a crystallinity of the at least one layer, or any combination of two or more thereof.

According to yet another embodiment, a method of treating a conductive element is described. The method includes: disposing a conductive element having a resistive property in a GCIB processing system; producing a GCIB in the GCIB processing system; exposing the conductive element to the GCIB to alter the resistive property of the conductive element; and adjusting a spatial variation of the resistive property for the conductive element across the substrate using the GCIB.

### BRIEF DESCRIPTION OF THE DRAWINGS

In the accompanying drawings:

FIGS. 1A through 1B illustrate a non-volatile memory device;

FIG. 2 is a flow chart illustrating a method for preparing a non- volatile memory device according to an embodiment;

FIG. 3 is a flow chart illustrating a method for preparing a non-volatile memory device according to another embodiment;

FIG. 4 is a flow chart illustrating a method of treating a conductive element according to yet another embodiment;

FIG. 5 is an illustration of a GCIB processing system;

FIG. 6 is another illustration of a GCIB processing system;

FIG. 7 is yet another illustration of a GCIB processing system;

FIG. 8 is an illustration of an ionization source for a GCIB processing system; and

FIG. 9 is an illustration of another ionization source for a GCIB processing system.

### DETAILED DESCRIPTION OF SEVERAL EMBODIMENTS

A method and system for fabricating a non-volatile memory device, such as a resistive-switching random access memory (ReRAM) device, using a gas cluster ion beam (GCIB) is disclosed in various embodiments. However, one skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

“Substrate” as used herein generically refers to the object being processed in accordance with the invention. The substrate may include any material portion or structure of a device, particularly a semiconductor or other electronics device, and may, for example, be a base substrate structure, such as a semiconductor wafer or a layer on or overlying a base substrate structure such as a thin film. Thus, substrate is not intended to be limited to any particular base structure, underlying layer or overlying layer, patterned or unpatterned, but rather, is contemplated to include any such layer or base structure, and any combination of layers and/or base structures. The description below may reference particular types of substrates, but this is for illustrative purposes only and not limitation.

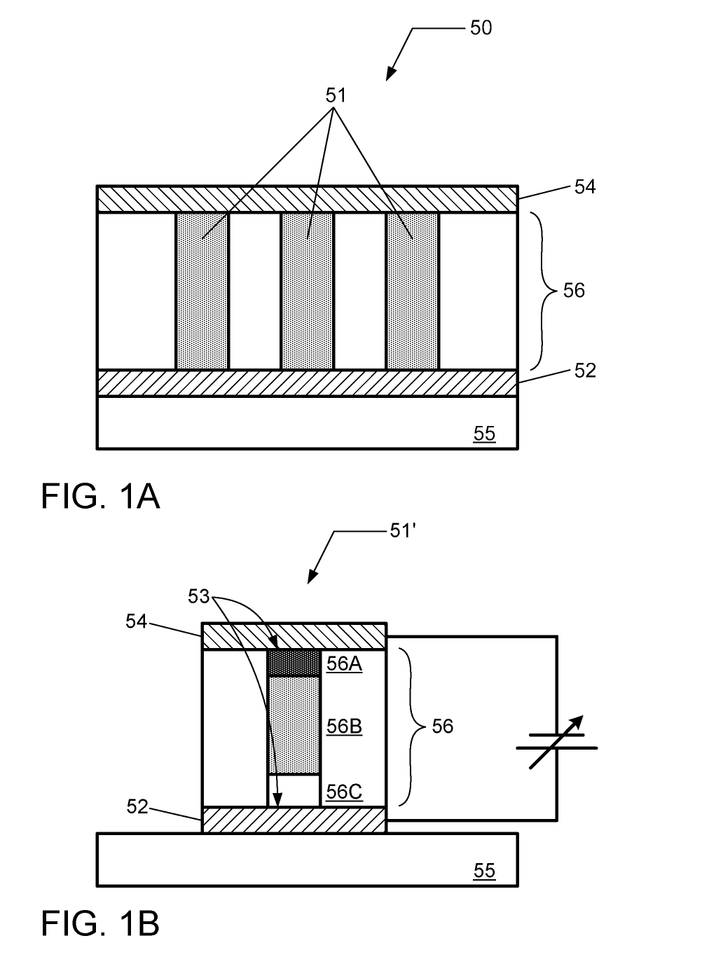

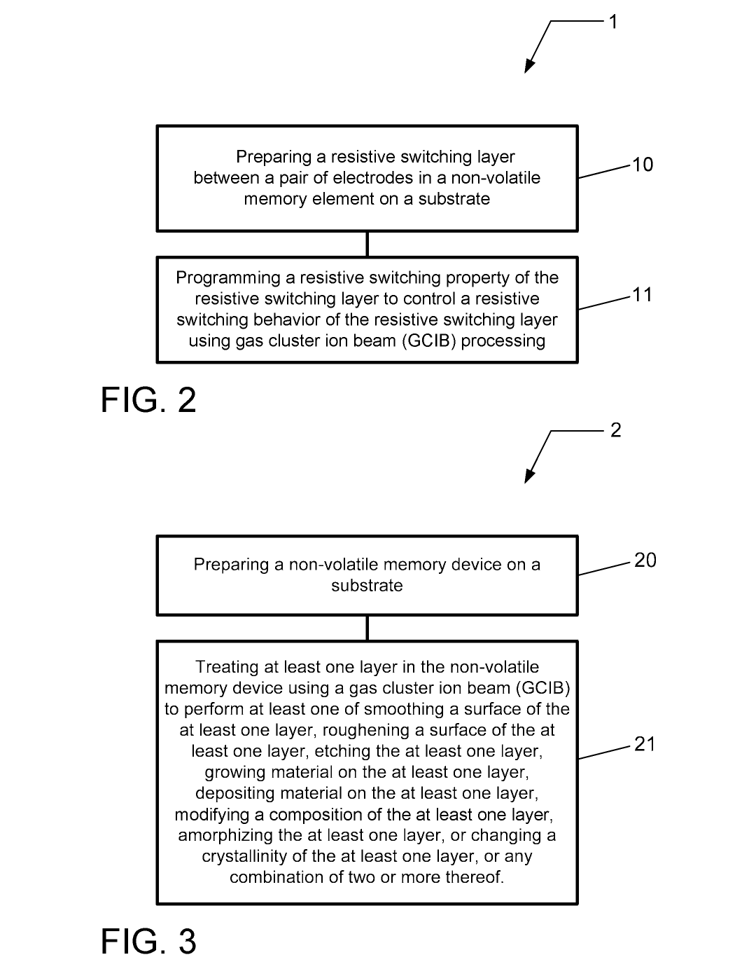

Referring now to the drawings wherein like reference numerals designate corresponding parts throughout the several views, a non-volatile memory device is described in FIGS. 1A and 1B. Furthermore, FIG. 2 provides a flow chart 1 illustrating a method of preparing a non-volatile memory device according to an embodiment. The non-volatile memory device may include a ReRAM device, such as a phase-change RAM (PCRAM) device or a conductive-bridging RAM (CBRAM) device.

In step 10 and as shown in FIGS. 1A and 1B, a resistive switching layer 56 is prepared between a pair of electrodes 52, 54 in a non-volatile memory element 50 on a substrate 55. The resistive switching layer 56 includes a conductive element or layer that may be programmed for two or more resistance states. The resistive switching layer 56 may include a transition metal oxide, a transition metal nitride, a transition metal oxynitride, or a chalcogenide. As illustrated in FIG. 1A, the non-volatile memory element 50 may include a plurality of memory cells 51

As illustrated in FIG. 1B for a selected memory cell 51′, the resistive switching layer 56 may include multiple layers and/or sub-layers 56A, 56B, 56C. While not shown in FIG. 1B, either of the pair of electrodes 52, 54 may include multiple layers, or sub-layers. The resistive switching layer 56 may include an element selected from the group consisting of Ge, Si, Cu, Ag, Ni, Ti, W, Hf, and V. At least one of the pair of electrodes 52, 54 may include Ag or Pt.

The resistive switching layer 56 and/or at least one of the pair of electrodes 52, 54 may be deposited using a vapor deposition process, such as a physical vapor deposition (PVD) process or variations thereof, a chemical vapor deposition (CVD) process or variations thereof, an epitaxial vapor deposition process or variations thereof, a non-epitaxial vapor deposition process or variations thereof, an electron beam evaporation deposition process or variations thereof, or an atomic layer deposition (ALD) process or variations thereof. Alternatively, at least a portion of the resistive switching layer 56 and/or at least one of the pair of electrodes 52, 54 may be grown or deposited using a GCIB. Prior to forming the resistive switching layer 56 and/or at least one of the pair of electrodes 52, 54, the substrate 55 may be cleaned using a dry and/or wet cleaning process.

In PCRAM devices, the resistive switching layer 56 is subjected to thermally-induced (i.e., via ohmic or Joule heating) reversible phase change between an amorphous phase and a crystalline phase. The amorphous phase imposes a high resistance state, and the crystalline phase imposes a low resistance state. Thus, two distinct resistive states may be utilized for information storage. During read operations, the high/low resistance state of the selected memory cell 51′ is assessed via a read voltage. During write operations, ohmic (or Joule) heating is achieved via a write voltage to alter the amorphous/crystalline phase and, hence, the resistance state. For example, to produce an amorphous phase, the current between the pair of electrodes 52, 54 is made sufficiently high to cause the temperature of the resistive switching layer 56 to exceed the melting temperature of the resistive switching layer 56 for a short period of time, followed by rapid cooling. Additionally, for example, to produce a crystalline phase, the current between the pair of electrodes 52, 54 is made sufficiently high to cause the temperature of the resistive switching layer 56 to exceed the glass transition temperature of the resistive switching layer 56 for a long period of time, yet remain less than the melting temperature.

In CBRAM devices, the resistive switching layer 56 is subjected to voltage changes across the pair of electrodes 52, 54 to induce changes in the resistance state of the resistive switching layer 56. Therein, under certain applied voltages, the resistive switching layer 56 behaves as an ion conductor layer, and at least one of the pair of electrodes 52, 54 serves as a source of metal ions to the ion conductor layer.

For some ion conductor layers, metal ions readily dissolve into the ion conductor layer. Thus, a critical/threshold voltage and its polarity may be used to impose a high resistance state or a low resistance state, which may be utilized for information storage. During read operations, the high/low resistance state of the selected memory cell 51′ is assessed via a read voltage. During write operations, the critical/threshold voltage and polarity, i.e., write voltage, is utilized to alter the resistance state. For example, at a critical voltage with a positive polarity, conductive precipitation within the ion conductor layer occurs, which causes conductive bridge formation and the creation of a low resistance state. Additionally, for example, at a critical voltage with a negative polarity, conductive precipitation is negated within the ion conductor layer, which causes disintegration of conductive bridge formation and the creation of a high resistance state.

For other ion conductor layers, metal ions do not readily dissolve into the ion conductor layer. Thus, a critical/threshold voltage may be used to create or destroy defects in the resistive switching layer 56 to impose a low resistance state or a high resistance state, which may be utilized for information storage. During read operations, the high/low resistance state of the selected memory cell 51′ is assessed via a read voltage. During write operations, critical/threshold voltage, i.e., write voltage, is utilized to alter the resistance state. For example, with a first voltage pulse, electric breakdown within the ion conductor layer occurs forming defects or defect filaments, which causes conductive path formation along the defects and the creation of a low resistance state. Additionally, for example, with a second voltage pulse, defects or defect filaments are negated within the ion conductor layer, which causes disintegration of conductive path formation and the creation of a high resistance state.

In 11, a resistive switching property of the resistive switching layer 56 is programmed to control a resistive switching behavior of the resistive switching layer 56 using GCIB processing. Therein, substrate 55 is disposed in a GCIB processing system, a GCIB is produced in the GCIB processing system according to a process recipe containing one or more GCIB process parameters selected to achieve the resistive switching property, and the resistive switching layer 56 is exposed to the GCIB.

In one embodiment, the resistive switching property may be programmed to achieve a resistance for a low resistance state, a resistance for a high resistance state, or a resistance range between a low resistance state and a high resistance state for the resistive switching behavior of the resistive switching layer 56.

In another embodiment, the resistive switching property may be programmed to achieve a resistivity and/or a temperature coefficient of resistivity in the resistive switching layer 56.

In another embodiment, the resistive switching property may be programmed to achieve a susceptibility for defect formation in the resistive switching layer 56, wherein the susceptibility for defect formation affects conductive path formation when switching between resistance states.

In another embodiment, the resistive switching property may be programmed to achieve a susceptibility for conductive precipitation in the resistive switching layer 56, wherein the susceptibility for conductive precipitation affects conductive bridge formation when switching between resistance states.

As an example, in a PCRAM device, the resistive switching layer 56 may include a heating layer, which when heated via ohmic heating causes a switch between an amorphous phase and a crystalline phase in the resistive switching layer 56, as described above. GCIB treatment may be used to alter the resistivity and/or temperature coefficient of resistivity in the heating layer.

As another example, in a CBRAM device, the resistive switching layer 56 may include an ion conductor layer that does not readily dissolve metal ions. GCIB treatment may be used to enhance the susceptibility for defect formation in the resistive switching layer 56. For instance, GCIB treatment of an interface 53 between at least one of the pair of electrodes 52, 54 and the resistive switching layer 56 may cause the formation of defect sites at interface 53 to act as a propagation site for defect/filament formation in the resistive switching layer 56 and the formation of conductive paths.

As yet another example, in a CBRAM device, the resistive switching layer 56 may include an ion conductor layer that does readily dissolve metal ions. GCIB treatment may be used to enhance the susceptibility for conductive precipitation in the resistive switching layer 56. For instance, GCIB treatment of the resistive switching layer 56 may cause the formation of sites for conductive bridge formation in the resistive switching layer 56.

In another embodiment, GCIB treatment may be configured to modify a chemical composition of the resistive switching layer 56. The GCIB may contain O, N, S, Se, Te, Si, Ge, He, Ne, Ar, Kr, or Xe, or any combination of two or more thereof. For example, the GCIB may be used to introduce O and/or N into the resistive switching layer 56.

In another embodiment, GCIB treatment may be configured to remove impurities from the resistive switching layer 56. For example, the GCIB may be used to remove C and/or H from the resistive switching layer 56.

In another embodiment, GCIB treatment may be configured to alter a thickness of the resistive switching layer 56 by etching material from the resistive switching layer 56, growing material on the resistive switching layer 56, or depositing material on the resistive switching layer 56.

In another embodiment, GCIB treatment may be configured to amorphize the resistive switching layer 56, or alter a crystallinity of the resistive switching layer 56.

In another embodiment, GCIB treatment may be configured to alter an interfacial roughness between the resistive switching layer 56 and at least one of the pair of electrodes 52, 54.

In yet another embodiment, GCIB treatment may be configured to adjust a spatial variation of the resistive switching property for the resistive switching layer 56 across the substrate 55. For example, the GCIB treatment may be configured to spatially tune the resistive switching property uniformly across the substrate 55, or differentially across the substrate 55.

The GCIB may be generated from a pressurized gas mixture that includes a noble gas (i.e., He, Ne, Ar, Kr, Xe). Additionally, the GCIB may be generated from a pressurized gas mixture that includes at least one element selected from the group consisting of He, Ne, Ar, Xe, Kr, B, C, Se, Te, Si, Ge, N, P, As, O, S, F, CI, and Br. Furthermore, the GCIB may be generated from a pressurized gas mixture that includes at least one film forming constituent for depositing or growing a thin film on the resistive switching layer 56.

The GCIB may be used to form a graded mixed layer in the resistive switching layer 56 having a pre-determined thickness on the substrate 55. Additionally, the GCIB may be used to form a graded mixed layer having a pre-determined interfacial roughness at an upper and/or a lower boundary of the graded mixed layer. Additionally, the graded mixed layer may include one or more dopants and/or impurities infused using the GCIB. Furthermore, the graded mixed layer may include a concentration profile extending partly or fully through the mixed layer that is tailored via adjustment of one or more GCIB processing parameters of the GCIB.

In addition to irradiation of the resistive switching layer 56 with the GCIB, another GCIB may be used for additional control and/or function. Irradiation of the substrate 55 by another GCIB may proceed before, during, or after use of the GCIB. For example, another GCIB may be used to dope a portion of the substrate 55 with an impurity. The doping may comprise introducing one or more elements selected from the group consisting of He, Ne, Ar, Xe, Kr, B, C, Se, Te, Si, Ge, N, P, As, O, S, F, CI, and Br.

The portion of the substrate 55 subjected to GCIB irradiation may be cleaned before or after the irradiating with the GCIB. For example, the cleaning process may include a dry cleaning process and/or a wet cleaning process. Additionally, the portion of the substrate 55 subjected to GCIB irradiation may be annealed after the irradiating with the GCIB.

Preceding, during, and/or following GCIB treatment, another GCIB treatment may be used to process at least one of the pair of electrodes 52, 54.

According to one embodiment, at least one portion of substrate 55 is exposed to one or more other GCIB treatments before, during, or after any one of the process steps described in FIGS. 1A and 1B. Furthermore, a cleaning step and/or an annealing step may be inserted before or after any one of the process steps described above.

As described above, one or more GCIB treatments may be performed to program, modify, and/or enhance a resistive switching property of a resistive switching layer 56 during the preparation of a non-volatile memory element 50 on a substrate 55. For any one of these GCIB treatments, a GCIB operation may comprise: establishing a GCIB; selecting a beam energy, a beam energy distribution, a beam focus, and a beam dose; accelerating the GCIB to achieve the beam energy; focusing the GCIB to achieve the beam focus; and exposing the portion of the substrate to the accelerated GCIB according to the beam dose. The GCIB treatment may further comprise selecting the beam energy and the beam dose to achieve a desired thickness of a mixed layer formed during the irradiating the portion of the substrate with the GCIB.

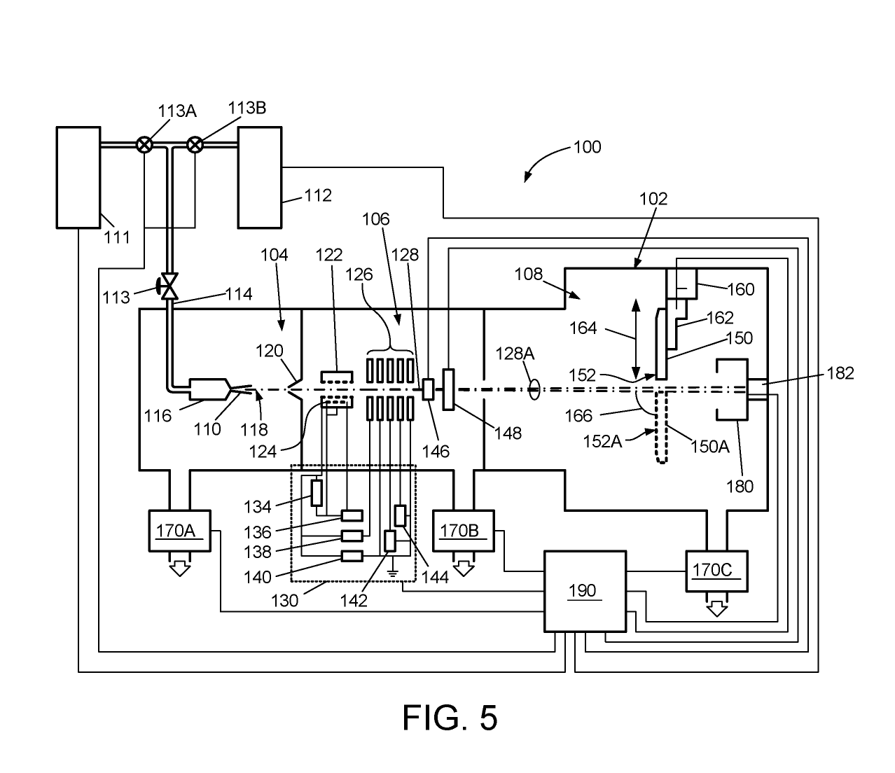

A GCIB may be established having an energy per atom ratio ranging from about 0.25 eV per atom to about 100 eV per atom. Alternatively, the GLIB may be established having an energy per atom ratio ranging from about 0.25 eV per atom to about 10 eV per atom. Alternatively, the GLIB may be established having an energy per atom ratio ranging from about 1 eV per atom to about 10 eV per atom. The GLIB can be formed in a GLIB processing system, such as any of the GLIB processing systems (100, 100′ or 100″) described below in FIG. 5, 6 or 7, or any combination thereof.

The substrate to be treated may be provided in a reduced-pressure environment in a GLIB processing system. The substrate may be positioned on a substrate holder and may be securely held by the substrate holder. The temperature of the substrate may or may not be controlled. For example, the substrate may be heated or cooled during a film forming process. The environment surrounding the substrate is maintained at a reduced pressure.

A GLIB may be generated in the reduced-pressure environment, and can be generated from a pressurized gas mixture. The pressurized gas mixture may use a material source comprising one or more gases containing elements selected from the group consisting of He, Ne, Ar, Kr, Xe, B, C, Se, Te, Si, Ge, N, P, As, O, S, F, and Cl. For example, the material source may comprise He, Ne, Ar, Kr, Xe, SiH₄, Si₂H₆, SiH₂Cl₂, SiCI₃H, methylsilane, dimethylsilane, trimethylsilane, tetramethylsilane, ethylsilane, diethylsilane, triethylsilane, tetraethylsilane, SiCl₄, SiF₄, GeH₄, Ge₂H₆, GeH₂Cl₂, GeCl₃H, methylgermane, dimethylgermane, trimethylgermane, tetramethylgermane, ethylgermane, diethylgermane, triethylgermane, tetraethylgermane, GeCl₄, GeF₄, N₂, H₂, O₂, NO, NO₂, N₂O, NH₃, NF₃, HCl, SF₆, CO, CO₂, C₂H₄, CH₄, C₂H₂, C₂H₆, C₃H₄, C₃H₆, C₃H₈, C₄H₆, C₄H₈, C₄H₁₀, C₅H₈, C₅H₁₀, C₆H₆, C₆H₁₀, C₆H₁₂, BF₃, B₂H₆, AsH₃, AsF₅, PH₃, PF₃, PCl_{S}, or PF_{S}, or any combination of two or more thereof.

A beam acceleration potential, a beam dose, a stagnation pressure, a stagnation temperature, a mass flow rate, a cluster size, a beam size, a beam composition, and/or beam electrode potential can be selected. The beam acceleration potential, the beam dose, the cluster size, and/or any one or more of the aforementioned GCIB properties can be selected to achieve pre-specified properties of the substrate. For example, the beam acceleration potential, cluster size, and/or beam dose may be adjusted to alter the material properties of the substrate, i.e., as will be described below, alter a concentration of one or more species within the substrate, a concentration profile of one or more species within the substrate, or depth of one or more species within the substrate, or any combination thereof. The beam acceleration potential may range up to 100 kV, the cluster size may range up to several tens of thousands of atoms, and the beam dose may range up to about 1×10¹⁷ clusters per cm². For example, the beam acceleration potential may range from about 1 kV to about 70 kV (i.e., the beam energy may range from about 1 keV to about 70 keV). Additionally, for example, the beam dose may range from about 1×10¹⁵ clusters per cm² to about 1×10¹⁷ clusters per cm².

The beam acceleration potential may be used to modify the depth of penetration of the one or more elements in the substrate, i.e., increasing the beam acceleration potential increases the depth and decreasing the beam acceleration potential decreases the depth. Additionally, the beam dose may be used to modify the concentration of the one or more elements in the substrate, i.e., increasing the beam dose increases the final concentration and decreasing the beam dose decrease the final concentration. The GCIB is accelerated according to the beam acceleration potential, and the substrate is exposed to the GCIB according to the beam dose.

Herein, beam dose is given the units of number of clusters per unit area. However, beam dose may also include beam current and/or time (e.g., GCIB dwell time). For example, the beam current may be measured and maintained constant, while time is varied to change the beam dose. Alternatively, for example, the rate at which clusters strike the surface of the substrate per unit area (i.e., number of clusters per unit area per unit time) may be held constant while the time is varied to change the beam dose.

Furthermore, the energy per atom ratio may be used to adjust the concentration of one or more elements present or not present in the substrate and/or the depth to which the one or more elements are present in the substrate. For instance, while decreasing the energy per atom ratio, the adjusted depth may be decreased. Alternatively, while increasing the energy per atom ratio, the adjusted depth may be increased.

The establishment of the GCIB having a desired energy per atom ratio may include selection of a beam acceleration potential, a stagnation pressure for formation of the GCIB, or a gas flow rate, or any combination thereof. The beam acceleration potential may be used to increase or decrease the beam energy or energy per ion cluster. For example, an increase in the beam acceleration potential causes an increase in the maximum beam energy and, consequently, an increase in the energy per atom ratio for a given cluster size. Additionally, the stagnation pressure may be used to increase or decrease the cluster size for a given cluster. For example, an increase in the stagnation pressure during formation of the GCIB causes an increase in the cluster size (i.e., number of atoms per cluster) and, consequently, a decrease in the energy per atom ratio for a given beam acceleration potential.

Additionally yet, other GCIB properties may be varied to adjust the amorphizing, doping or modification of the substrate including, but not limited to, beam energy distribution, cluster size distribution, or gas nozzle design (such as nozzle throat diameter, nozzle length, and/or nozzle divergent section half-angle).

Furthermore, as described above, one or more thermal anneals may be performed to program, modify, and/or enhance a resistive switching property of resistive switching layer 56 during the preparation of non-volatile memory element 50 on substrate 55. For any one of these thermal anneals, the substrate may be subjected to a thermal treatment, wherein the temperature of the substrate is elevated to a material-specific temperature for a period of time. The temperature and the time for the annealing process may be adjusted in order to vary the properties of the substrate. For example, the temperature of the substrate may be elevated to a value greater than about 800 degrees C. Additionally, for example, the temperature of the substrate may be elevated to a value greater than about 850 degrees C. Additionally yet, for example, the temperature of the substrate may be elevated to a value greater than about 900 degrees C. Furthermore, for example, the time for the annealing process may be greater than about 1 millisecond. The annealing process may be performed at atmospheric pressure or reduced pressure. Additionally, the annealing process may be performed with or without an inert gas atmosphere. Furthermore, the annealing process may be performed in a furnace, a rapid thermal annealing (RTP) system, a flash lamp annealing system, or a laser annealing system.

Referring now to FIG. 3, a method of preparing a non-volatile memory device is described according to another embodiment. The method comprises a flow chart 2 beginning in 20 with preparing a non-volatile memory device on a substrate, wherein the non-volatile memory device includes a ReRAM device, such as a PCRAM device or a CBRAM device. In 21, at least one layer in the non-volatile memory device is treated using a GCIB to perform at least one of smoothing a surface of the at least one layer, roughening a surface of the at least one layer, etching the at least one layer, growing material on the at least one layer, depositing material on the at least one layer, modifying a composition the at least one layer, amorphizing the at least one layer, or changing a crystallinity of the at least one layer, or any combination of two or more thereof.

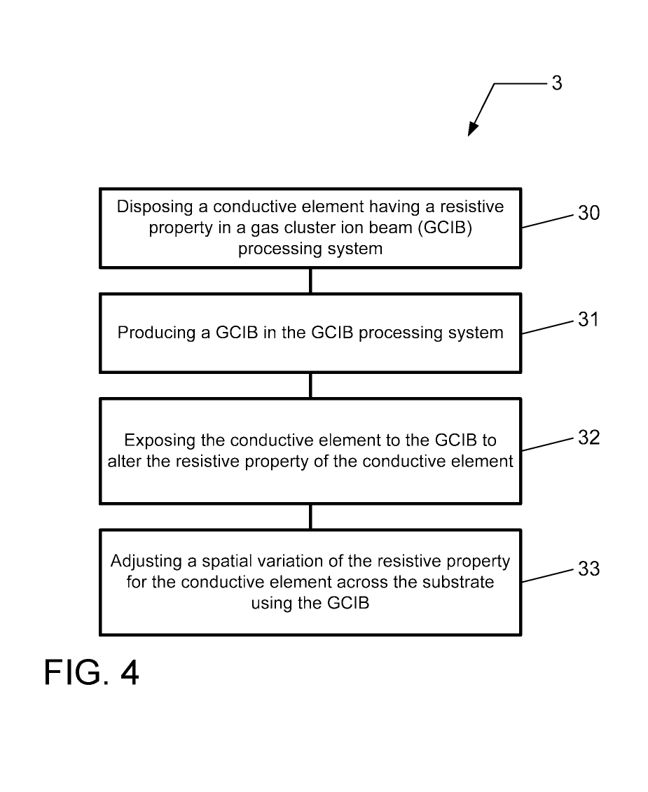

Referring now to FIG. 4, a method of treating a conductive element of a non-volatile memory device is described according to yet another embodiment. The method comprises a flow chart 3 beginning in 30 with disposing a conductive element having a resistive property in a GCIB processing system.

In 31, a GCIB in said GCIB processing system is produced.

In 32, the conductive element is exposed to the GCIB to alter the resistive property of the conductive element.

In 33, a spatial variation of the resistive property for the conductive element is adjusted across the substrate using the GCIB. For example, the GCIB may be configured to spatially tune the resistive property uniformly across the substrate, or differentially across the substrate.

The method may further include acquiring metrology data for a substrate and/or at least one conductive element on the substrate.

Metrology data may be acquired using a metrology system coupled to a GCIB processing system, either in-situ or ex-situ. The metrology system may comprise any variety of substrate diagnostic systems including, but not limited to, optical diagnostic systems, X-ray fluorescence spectroscopy systems, four-point probing systems, transmission-electron microscope (TEM), atomic force microscope (AFM), scanning-electron microscope (SEM), etc. Additionally, the metrology system may comprise an optical digital profilometer (ODP), a scatterometer, an ellipsometer, a reflectometer, an interferometer, or any combination of two or more thereof.

For example, the metrology system may constitute an optical scatterometry system. The scatterometry system may include a scatterometer, incorporating beam profile ellipsometry (ellipsometer) and beam profile reflectometry (reflectometer), commercially available from Therma-Wave, Inc. (1250 Reliance Way, Fremont, Calif. 94539) or Nanometrics, Inc. (1550 Buckeye Drive, Milpitas, Calif. 95035). Additionally, for example, the in-situ metrology system may include an integrated Optical Digital Profilometry (iODP) scatterometry module configured to measure metrology data on a substrate.

The metrology data can include parametric data, such as geometrical, mechanical, electrical and/or optical parameters associated with the substrate, any layer formed on the substrate, and/or any portion of the conductive element. For example, metrology data can include any parameter measurable by the metrology systems described above. Additionally, for example, metrology data can include a film thickness, a surface/interface roughness, a surface contamination, a feature depth, a trench depth, a via depth, a feature width, a trench width, a via width, a critical dimension (CD), an electrical resistance, or any combination of two or more thereof.

The metrology data is measured at two or more locations on the substrate. Moreover, this data may be acquired and collected for one or more substrates. The one or more substrates may, for instance, include a cassette of substrates. The metrology data is measured at two or more locations on at least one of the one or more substrates and may, for example, be acquired at a plurality of locations on each of the one or more substrates. Thereafter, the plurality of locations on each of the plurality of substrates can be expanded from measured sites to unmeasured sites using a data fitting algorithm. For example, the data fitting algorithm can include interpolation (linear or nonlinear) or extrapolation (linear or nonlinear) or a combination thereof.

Once metrology data is collected for the one or more substrates using the metrology system, the metrology data is provided to a controller for computing correction data. Metrology data can be communicated between the metrology system and the controller via a physical connection (e.g., a cable), or a wireless connection, or a combination thereof. Additionally, the metrology data can be communicated via an intranet or internet connection. Alternatively, metrology data may be communicated between the metrology system and the controller via a computer readable medium.

The correction data is computed for location specific processing of the substrate and/or the at least one conductive element on the substrate. The correction data for a given substrate comprises a process condition for modulation of the GCIB dose as a function of position on the substrate in order to achieve a change between the parametric data associated with the incoming metrology data and the target parametric data for the given substrate. For example, the correction data for a given substrate can comprise determining a process condition for using the GCIB to correct a non-uniformity of the parametric data for the given substrate. Alternatively, for example, the correction data for a given substrate can comprise determining a process condition for using the GCIB to create a specifically intended non-uniformity of the parametric data for the given substrate.

Using an established relationship between the desired change in parametric data and the GCIB dose and an established relationship between the GCIB dose and a GCIB process condition having a set of GCIB processing parameters, the controller determines correction data for each substrate. For example, a mathematical algorithm can be employed to take the parametric data associated with the incoming metrology data, compute a difference between the incoming parametric data and the target parametric data, invert the GCIB processing pattern (i.e., etching pattern or deposition pattern or both) to fit this difference, and create a beam dose contour to achieve the GCIB processing pattern using the relationship between the change in parametric data and the GCIB dose. Thereafter, for example, GCIB processing parameters can be determined to affect the calculated beam dose contour using the relationship between the beam dose and the GCIB process condition. The GCIB processing parameters can include a beam dose, a beam area, a beam profile, a beam intensity, a beam scanning rate, or an exposure time (or beam dwell time), or any combination of two or more thereof.

Many different approaches to the selection of mathematical algorithm may be successfully employed in this embodiment. In another embodiment, the beam dose contour may selectively deposit additional material in order to achieve the desired change in parametric data.

The correction data is applied to the substrate and/or the at least one conductive element on the substrate using a GCIB. During corrective processing, the GCIB may be configured to perform at least one of smoothing, amorphizing, modifying, doping, etching, growing, or depositing, or any combination of two or more thereof. The application of the corrective data to the substrate may facilitate correction of substrate defects, correction of light emitting device stack layer defects, correction of substrate surface planarity, correction of layer thickness, or improvement of layer adhesion. Once processed to GCIB specifications, the uniformity of the substrate(s) or distribution of the parametric data for the substrate(s) may be examined either in-situ or ex-situ, and the process may be finished or refined as appropriate.

Referring now to FIG. 5, a GCIB processing system 100 for treating a substrate as described above is depicted according to an embodiment. The GCIB processing system 100 comprises a vacuum vessel 102, substrate holder 150, upon which a substrate 152 to be processed is affixed, and vacuum pumping systems 170A, 170B, and 170C. Substrate 152 can be a semiconductor substrate, a wafer, a flat panel display (FPD), a liquid crystal display (LCD), or any other workpiece. GCIB processing system 100 is configured to produce a GCIB for treating substrate 152.

Referring still to GCIB processing system 100 in FIG. 5, the vacuum vessel 102 comprises three communicating chambers, namely, a source chamber 104, an ionization/acceleration chamber 106, and a processing chamber 108 to provide a reduced-pressure enclosure. The three chambers are evacuated to suitable operating pressures by vacuum pumping systems 170A, 170B, and 170C, respectively. In the three communicating chambers 104, 106, 108, a gas cluster beam can be formed in the first chamber (source chamber 104), while a GCIB can be formed in the second chamber (ionization/acceleration chamber 106) wherein the gas cluster beam is ionized and accelerated. Then, in the third chamber (processing chamber 108), the accelerated GCIB may be utilized to treat substrate 152.

Although specific examples are provided for transistor gate and trench capacitor applications, the methods of etching, as described above, may be utilized in any substrate processing wherein etching is necessitated.

As shown in FIG. 5, GCIB processing system 100 can comprise one or more gas sources configured to introduce one or more gases or mixture of gases to vacuum vessel 102. For example, a first gas composition stored in a first gas source 111 is admitted under pressure through a first gas control valve 113A to a gas metering valve or valves 113. Additionally, for example, a second gas composition stored in a second gas source 112 is admitted under pressure through a second gas control valve 113B to the gas metering valve or valves 113. Further, for example, the first gas composition or second gas composition or both can include a condensable inert gas, carrier gas or dilution gas. For example, the inert gas, carrier gas or dilution gas can include a noble gas, i.e., He, Ne, Ar, Kr, Xe, or Rn.

Furthermore, the first gas source 111 and the second gas source 112 may be utilized either alone or in combination with one another to produce ionized clusters. The material composition can include the principal atomic or molecular species of the elements desired to be introduced to the material layer.

The high pressure, condensable gas comprising the first gas composition or the second gas composition or both is introduced through gas feed tube 114 into stagnation chamber 116 and is ejected into the substantially lower pressure vacuum through a properly shaped nozzle 110. As a result of the expansion of the high pressure, condensable gas from the stagnation chamber 116 to the lower pressure region of the source chamber 104, the gas velocity accelerates to supersonic speeds and gas cluster beam 118 emanates from nozzle 110.

The inherent cooling of the jet as static enthalpy is exchanged for kinetic energy, which results from the expansion in the jet, causes a portion of the gas jet to condense and form a gas cluster beam 118 having clusters, each consisting of from several to several thousand weakly bound atoms or molecules. A gas skimmer 120, positioned downstream from the exit of the nozzle 110 between the source chamber 104 and ionization/acceleration chamber 106, partially separates the gas molecules on the peripheral edge of the gas cluster beam 118, that may not have condensed into a cluster, from the gas molecules in the core of the gas cluster beam 118, that may have formed clusters. Among other reasons, this selection of a portion of gas cluster beam 118 can lead to a reduction in the pressure in the downstream regions where higher pressures may be detrimental (e.g., ionizer 122, and processing chamber 108). Furthermore, gas skimmer 120 defines an initial dimension for the gas cluster beam entering the ionization/acceleration chamber 106.

After the gas cluster beam 118 has been formed in the source chamber 104, the constituent gas clusters in gas cluster beam 118 are ionized by ionizer 122 to form GCIB 128. The ionizer 122 may include an electron impact ionizer that produces electrons from one or more filaments 124, which are accelerated and directed to collide with the gas clusters in the gas cluster beam 118 inside the ionization/acceleration chamber 106. Upon collisional impact with the gas cluster, electrons of sufficient energy eject electrons from molecules in the gas clusters to generate ionized molecules. The ionization of gas clusters can lead to a population of charged gas cluster ions, generally having a net positive charge.

As shown in FIG. 5, beam electronics 130 are utilized to ionize, extract, accelerate, and focus the GCIB 128. The beam electronics 130 include a filament power supply 136 that provides voltage V_{F} to heat the ionizer filament 124.

Additionally, the beam electronics 130 include a set of suitably biased high voltage electrodes 126 in the ionization/acceleration chamber 106 that extracts the cluster ions from the ionizer 122. The high voltage electrodes 126 then accelerate the extracted cluster ions to a desired energy and focus them to define GCIB 128. The kinetic energy of the cluster ions in GCIB 128 typically ranges from about 1000 electron volts (1 keV) to several tens of keV. For example, GCIB 128 can be accelerated to 1 to 100 keV.

As illustrated in FIG. 4, the beam electronics 130 further include an anode power supply 134 that provides voltage V_{A} to an anode of ionizer 122 for accelerating electrons emitted from filament 124 and causing the electrons to bombard the gas clusters in gas cluster beam 118, which produces cluster ions.

Additionally, as illustrated in FIG. 4, the beam electronics 130 include an extraction power supply 138 that provides voltage V_{EE} to bias at least one of the high voltage electrodes 126 to extract ions from the ionizing region of ionizer 122 and to form the GCIB 128. For example, extraction power supply 138 provides a voltage to a first electrode of the high voltage electrodes 126 that is less than or equal to the anode voltage of ionizer 122.

Furthermore, the beam electronics 130 can include an accelerator power supply 140 that provides voltage _{VACC} to bias one of the high voltage electrodes 126 with respect to the ionizer 122 so as to result in a total GCIB acceleration energy equal to about V_{ACC} electron volts (eV). For example, accelerator power supply 140 provides a voltage to a second electrode of the high voltage electrodes 126 that is less than or equal to the anode voltage of ionizer 122 and the extraction voltage of the first electrode.

Further yet, the beam electronics 130 can include lens power supplies 142, 144 that may be provided to bias some of the high voltage electrodes 126 with potentials (e.g., V_{D} and V_{L2}) to focus the GCIB 128. For example, lens power supply 142 can provide a voltage to a third electrode of the high voltage electrodes 126 that is less than or equal to the anode voltage of ionizer 122, the extraction voltage of the first electrode, and the accelerator voltage of the second electrode, and lens power supply 144 can provide a voltage to a fourth electrode of the high voltage electrodes 126 that is less than or equal to the anode voltage of ionizer 122, the extraction voltage of the first electrode, the accelerator voltage of the second electrode, and the first lens voltage of the third electrode.

Note that many variants on both the ionization and extraction schemes may be used. While the scheme described here is useful for purposes of instruction, another extraction scheme involves placing the ionizer and the first element of the extraction electrode(s) (or extraction optics) at V_{ACC}. This typically requires fiber optic programming of control voltages for the ionizer power supply, but creates a simpler overall optics train. The invention described herein is useful regardless of the details of the ionizer and extraction lens biasing.

A beam filter 146 in the ionization/acceleration chamber 106 downstream of the high voltage electrodes 126 can be utilized to eliminate monomers, or monomers and light cluster ions from the GCIB 128 to define a filtered process GCIB 128A that enters the processing chamber 108. In one embodiment, the beam filter 146 substantially reduces the number of clusters having 100 or less atoms or molecules or both. The beam filter may comprise a magnet assembly for imposing a magnetic field across the GCIB 128 to aid in the filtering process.

Referring still to FIG. 5, a beam gate 148 is disposed in the path of GCIB 128 in the ionization/acceleration chamber 106. Beam gate 148 has an open state in which the GCIB 128 is permitted to pass from the ionization/acceleration chamber 106 to the processing chamber 108 to define process GCIB 128A, and a closed state in which the GCIB 128 is blocked from entering the processing chamber 108. A control cable conducts control signals from control system 190 to beam gate 148. The control signals controllably switch beam gate 148 between the open or closed states.

A substrate 152, which may be a wafer or semiconductor wafer, a flat panel display (FPD), a liquid crystal display (LCD), or other substrate to be processed by GCIB processing, is disposed in the path of the process GCIB 128A in the processing chamber 108. Because most applications contemplate the processing of large substrates with spatially uniform results, a scanning system may be desirable to uniformly scan the process GCIB 128A across large areas to produce spatially homogeneous results.

An X-scan actuator 160 provides linear motion of the substrate holder 150 in the direction of X-scan motion (into and out of the plane of the paper). A Y-scan actuator 162 provides linear motion of the substrate holder 150 in the direction of Y-scan motion 164, which is typically orthogonal to the X-scan motion. The combination of X-scanning and Y-scanning motions translates the substrate 152, held by the substrate holder 150, in a raster-like scanning motion through process GCIB 128A to cause a uniform (or otherwise programmed) irradiation of a surface of the substrate 152 by the process GCIB 128A for processing of the substrate 152.

The substrate holder 150 disposes the substrate 152 at an angle with respect to the axis of the process GCIB 128A so that the process GCIB 128A has an angle of beam incidence 166 with respect to a substrate 152 surface. The angle of beam incidence 166 may be 90 degrees or some other angle, but is typically 90 degrees or near 90 degrees. During Y-scanning, the substrate 152 and the substrate holder 150 move from the shown position to the alternate position “A” indicated by the designators 152A and 150A, respectively. Notice that in moving between the two positions, the substrate 152 is scanned through the process GCIB 128A, and in both extreme positions, is moved completely out of the path of the process GCIB 128A (over-scanned). Though not shown explicitly in FIG. 5, similar scanning and over-scan is performed in the (typically) orthogonal X-scan motion direction (in and out of the plane of the paper).

A beam current sensor 180 may be disposed beyond the substrate holder 150 in the path of the process GCIB 128A so as to intercept a sample of the process GCIB 128A when the substrate holder 150 is scanned out of the path of the process GCIB 128A. The beam current sensor 180 is typically a Faraday cup or the like, closed except for a beam-entry opening, and is typically affixed to the wall of the vacuum vessel 102 with an electrically insulating mount 182.

As shown in FIG. 5, control system 190 connects to the X-scan actuator 160 and the Y-scan actuator 162 through electrical cable and controls the X-scan actuator 160 and the Y-scan actuator 162 in order to place the substrate 152 into or out of the process GCIB 128A and to scan the substrate 152 uniformly relative to the process GCIB 128A to achieve desired processing of the substrate 152 by the process GCIB 128A. Control system 190 receives the sampled beam current collected by the beam current sensor 180 by way of an electrical cable and, thereby, monitors the GCIB and controls the GCIB dose received by the substrate 152 by removing the substrate 152 from the process GCIB 128A when a predetermined dose has been delivered.

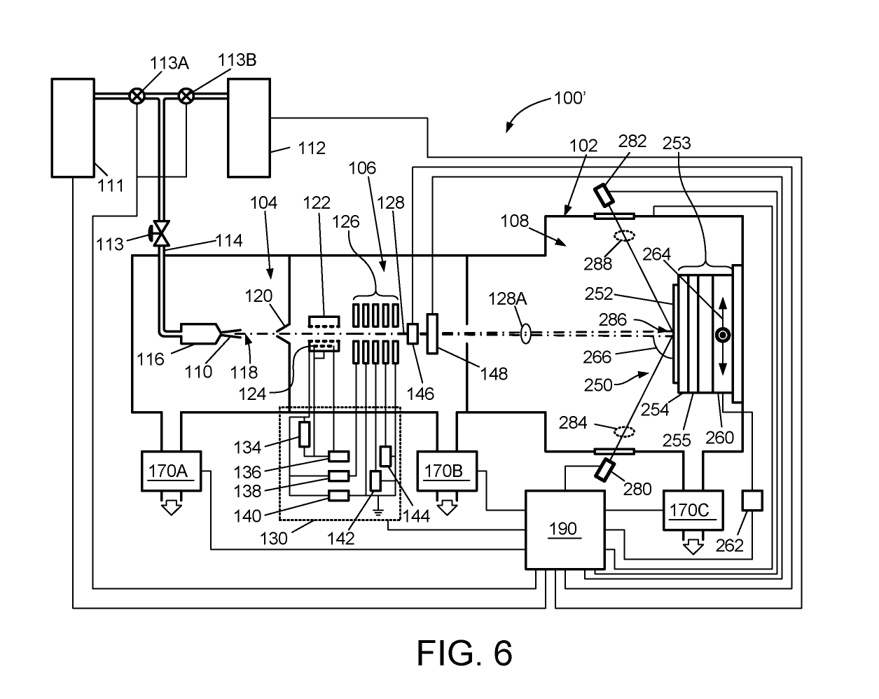

In the embodiment shown in FIG. 6, the GCIB processing system 100′ can be similar to the embodiment of FIG. 5 and further comprise a X-Y positioning table 253 operable to hold and move a substrate 252 in two axes, effectively scanning the substrate 252 relative to the process GCIB 128A. For example, the X-motion can include motion into and out of the plane of the paper, and the Y-motion can include motion along direction 264.

The process GCIB 128A impacts the substrate 252 at a projected impact region 286 on a surface of the substrate 252, and at an angle of beam incidence 266 with respect to the surface of substrate 252. By X-Y motion, the X-Y positioning table 253 can position each portion of a surface of the substrate 252 in the path of process GCIB 128A so that every region of the surface may be made to coincide with the projected impact region 286 for processing by the process GCIB 128A. An X-Y controller 262 provides electrical signals to the X-Y positioning table 253 through an electrical cable for controlling the position and velocity in each of X-axis and Y-axis directions. The X-Y controller 262 receives control signals from, and is operable by, control system 190 through an electrical cable. X-Y positioning table 253 moves by continuous motion or by stepwise motion according to conventional X-Y table positioning technology to position different regions of the substrate 252 within the projected impact region 286. In one embodiment, X-Y positioning table 253 is programmably operable by the control system 190 to scan, with programmable velocity, any portion of the substrate 252 through the projected impact region 286 for GCIB processing by the process GCIB 128A.

The substrate holding surface 254 of positioning table 253 is electrically conductive and is connected to a dosimetry processor operated by control system 190. An electrically insulating layer 255 of positioning table 253 isolates the substrate 252 and substrate holding surface 254 from the base portion 260 of the positioning table 253. Electrical charge induced in the substrate 252 by the impinging process GCIB 128A is conducted through substrate 252 and substrate holding surface 254, and a signal is coupled through the positioning table 253 to control system 190 for dosimetry measurement. Dosimetry measurement has integrating means for integrating the GCIB current to determine a GCIB processing dose. Under certain circumstances, a target-neutralizing source (not shown) of electrons, sometimes referred to as electron flood, may be used to neutralize the process GCIB 128A. In such case, a Faraday cup (not shown, but which may be similar to beam current sensor 180 in FIG. 5) may be used to assure accurate dosimetry despite the added source of electrical charge, the reason being that typical Faraday cups allow only the high energy positive ions to enter and be measured.

In operation, the control system 190 signals the opening of the beam gate 148 to irradiate the substrate 252 with the process GCIB 128A. The control system 190 monitors measurements of the GCIB current collected by the substrate 252 in order to compute the accumulated dose received by the substrate 252. When the dose received by the substrate 252 reaches a predetermined dose, the control system 190 closes the beam gate 148 and processing of the substrate 252 is complete. Based upon measurements of the GCIB dose received for a given area of the substrate 252, the control system 190 can adjust the scan velocity in order to achieve an appropriate beam dwell time to treat different regions of the substrate 252.

Alternatively, the process GCIB 128A may be scanned at a constant velocity in a fixed pattern across the surface of the substrate 252; however, the GCIB intensity is modulated (may be referred to as Z-axis modulation) to deliver an intentionally non-uniform dose to the sample. The GCIB intensity may be modulated in the GCIB processing system 100′ by any of a variety of methods, including varying the gas flow from a GCIB source supply; modulating the ionizer 122 by either varying a filament voltage VF or varying an anode voltage VA; modulating the lens focus by varying lens voltages VL1 and/or VL2; or mechanically blocking a portion of the GCIB with a variable beam block, adjustable shutter, or variable aperture. The modulating variations may be continuous analog variations or may be time modulated switching or gating.

The processing chamber 108 may further include an in-situ metrology system. For example, the in-situ metrology system may include an optical diagnostic system having an optical transmitter 280 and optical receiver 282 configured to illuminate substrate 252 with an incident optical signal 284 and to receive a scattered optical signal 288 from substrate 252, respectively. The optical diagnostic system comprises optical windows to permit the passage of the incident optical signal 284 and the scattered optical signal 288 into and out of the processing chamber 108. Furthermore, the optical transmitter 280 and the optical receiver 282 may comprise transmitting and receiving optics, respectively. The optical transmitter 280 receives, and is responsive to, controlling electrical signals from the control system 190. The optical receiver 282 returns measurement signals to the control system 190.

The in-situ metrology system may comprise any instrument configured to monitor the progress of the GCIB processing. According to one embodiment, the in-situ metrology system may constitute an optical scatterometry system. The scatterometry system may include a scatterometer, incorporating beam profile ellipsometry (ellipsometer) and beam profile reflectometry (reflectometer), commercially available from Therma-Wave, Inc. (1250 Reliance Way, Fremont, Calif. 94539) or Nanometrics, Inc. (1550 Buckeye Drive, Milpitas, Calif. 95035).

For instance, the in-situ metrology system may include an integrated Optical Digital Profilometry (iODP) scatterometry module configured to measure process performance data resulting from the execution of a treatment process in the GCIB processing system 100′. The metrology system may, for example, measure or monitor metrology data resulting from the treatment process. The metrology data can, for example, be utilized to determine process performance data that characterizes the treatment process, such as a process rate, a relative process rate, a feature profile angle, a critical dimension, a feature thickness or depth, a feature shape, etc. For example, in a process for directionally depositing material on a substrate, process performance data can include a critical dimension (CD), such as a top, middle or bottom CD in a feature (i.e., via, line, etc.), a feature depth, a material thickness, a sidewall angle, a sidewall shape, a deposition rate, a relative deposition rate, a spatial distribution of any parameter thereof, a parameter to characterize the uniformity of any spatial distribution thereof, etc. Operating the X-Y positioning table 253 via control signals from control system 190, the in-situ metrology system can map one or more characteristics of the substrate 252.

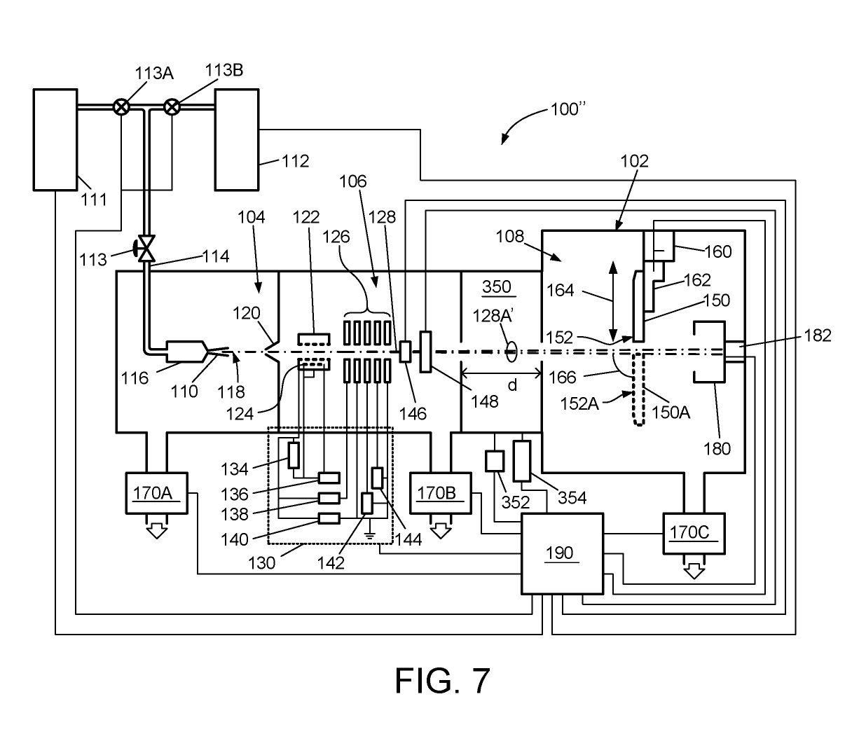

In the embodiment shown in FIG. 7, the GCIB processing system 100″ can be similar to the embodiment of FIG. 5 and further comprise a pressure cell chamber 350 positioned, for example, at or near an outlet region of the ionization/acceleration chamber 106. The pressure cell chamber 350 comprises an inert gas source 352 configured to supply a background gas to the pressure cell chamber 350 for elevating the pressure in the pressure cell chamber 350, and a pressure sensor 354 configured to measure the elevated pressure in the pressure cell chamber 350.

The pressure cell chamber 350 may be configured to modify the beam energy distribution of GCIB 128 to produce a modified processing GCIB 128A′. This modification of the beam energy distribution is achieved by directing GCIB 128 along a GCIB path through an increased pressure region within the pressure cell chamber 350 such that at least a portion of the GCIB traverses the increased pressure region. The extent of modification to the beam energy distribution may be characterized by a pressure-distance integral along the at least a portion of the GCIB path, where distance (or length of the pressure cell chamber 350) is indicated by path length (d). When the value of the pressure-distance integral is increased (either by increasing the pressure and/or the path length (d)), the beam energy distribution is broadened and the peak energy is decreased. When the value of the pressure-distance integral is decreased (either by decreasing the pressure and/or the path length (d)), the beam energy distribution is narrowed and the peak energy is increased. Further details for the design of a pressure cell may be determined from U.S. Pat. No. 7,060,989, entitled “Method and apparatus for improved processing with a gas-cluster ion beam”; the content of which is incorporated herein by reference in its entirety.

Control system 190 comprises a microprocessor, memory, and a digital I/O port capable of generating control voltages sufficient to communicate and activate inputs to GCIB processing system 100 (or 100′, 100″), as well as monitor outputs from GCIB processing system 100 (or 100′, 100″). Moreover, control system 190 can be coupled to and can exchange information with vacuum pumping systems 170A, 170B, and 170C, first gas source 111, second gas source 112, first gas control valve 113A, second gas control valve 113B, beam electronics 130, beam filter 146, beam gate 148, the X-scan actuator 160, the Y-scan actuator 162, and beam current sensor 180. For example, a program stored in the memory can be utilized to activate the inputs to the aforementioned components of GCIB processing system 100 according to a process recipe in order to perform a GCIB process on substrate 152.

However, the control system 190 may be implemented as a general purpose computer system that performs a portion or all of the microprocessor based processing steps of the invention in response to a processor executing one or more sequences of one or more instructions contained in a memory. Such instructions may be read into the controller memory from another computer readable medium, such as a hard disk or a removable media drive. One or more processors in a multi-processing arrangement may also be employed as the controller microprocessor to execute the sequences of instructions contained in main memory. In alternative embodiments, hard-wired circuitry may be used in place of or in combination with software instructions. Thus, embodiments are not limited to any specific combination of hardware circuitry and software.

The control system 190 can be used to configure any number of processing elements, as described above, and the control system 190 can collect, provide, process, store, and display data from processing elements. The control system 190 can include a number of applications, as well as a number of controllers, for controlling one or more of the processing elements. For example, control system 190 can include a graphic user interface (GUI) component (not shown) that can provide interfaces that enable a user to monitor and/or control one or more processing elements.

Control system 190 can be locally located relative to the GCIB processing system 100 (or 100′, 100″), or it can be remotely located relative to the GCIB processing system 100 (or 100′, 100″). For example, control system 190 can exchange data with GCIB processing system 100 using a direct connection, an intranet, and/or the internet. Control system 190 can be coupled to an intranet at, for example, a customer site (i.e., a device maker, etc.), or it can be coupled to an intranet at, for example, a vendor site (i.e., an equipment manufacturer). Alternatively or additionally, control system 190 can be coupled to the internet. Furthermore, another computer (i.e., controller, server, etc.) can access control system 190 to exchange data via a direct connection, an intranet, and/or the internet.

Substrate 152 (or 252) can be affixed to the substrate holder 150 (or substrate holder 250) via a clamping system (not shown), such as a mechanical clamping system or an electrical clamping system (e.g., an electrostatic clamping system). Furthermore, substrate holder 150 (or 250) can include a heating system (not shown) or a cooling system (not shown) that is configured to adjust and/or control the temperature of substrate holder 150 (or 250) and substrate 152 (or 252).

Vacuum pumping systems 170A, 170B, and 170C can include turbo-molecular vacuum pumps (TMP) capable of pumping speeds up to about 5000 liters per second (and greater) and a gate valve for throttling the chamber pressure. In conventional vacuum processing devices, a 1000 to 3000 liter per second TMP can be employed. TMPs are useful for low pressure processing, typically less than about 50 mTorr. Although not shown, it may be understood that pressure cell chamber 350 may also include a vacuum pumping system. Furthermore, a device for monitoring chamber pressure (not shown) can be coupled to the vacuum vessel 102 or any of the three vacuum chambers 104, 106, 108. The pressure-measuring device can be, for example, a capacitance manometer or ionization gauge.

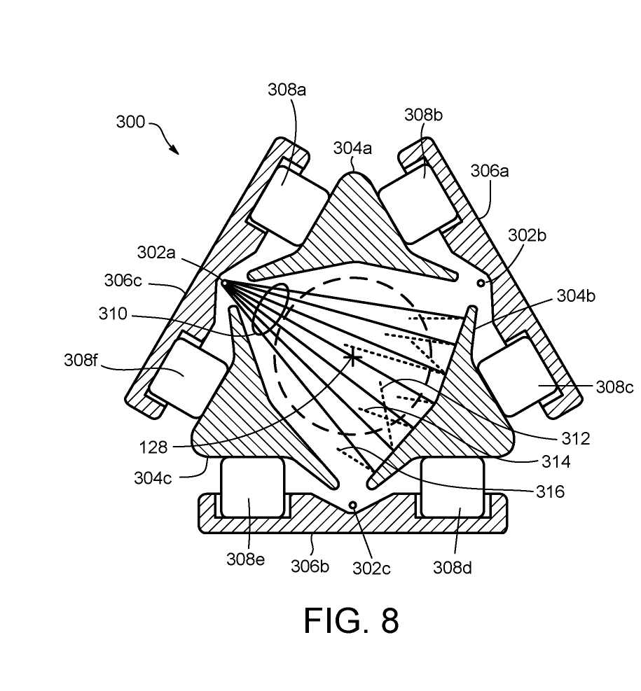

Referring now to FIG. 8, a section 300 of a gas cluster ionizer (122, FIGS. 5, 6 and 7) for ionizing a gas cluster jet (gas cluster beam 118, FIGS. 5, 6 and 7) is shown. The section 300 is normal to the axis of GCIB 128. For typical gas cluster sizes (2000 to 15000 atoms), clusters leaving the skimmer aperture (120, FIGS. 5, 6 and 7) and entering an ionizer (122, FIGS. 5, 6 and 7) will travel with a kinetic energy of about 130 to 1000 electron volts (eV). At these low energies, any departure from space charge neutrality within the ionizer 122 will result in a rapid dispersion of the jet with a significant loss of beam current. FIG. 8 illustrates a self-neutralizing ionizer. As with other ionizers, gas clusters are ionized by electron impact. In this design, thermo-electrons (seven examples indicated by 310) are emitted from multiple linear thermionic filaments 302a, 302b, and 302c (typically tungsten) and are extracted and focused by the action of suitable electric fields provided by electron-repeller electrodes 306a, 306b, and 306c and beam-forming electrodes 304a, 304b, and 304c. Thermo-electrons 310 pass through the gas cluster jet and the jet axis and then strike the opposite beam-forming electrode 304b to produce low energy secondary electrons (312, 314, and 316 indicated for examples).

Though (for simplicity) not shown, linear thermionic filaments 302b and 302c also produce thermo-electrons that subsequently produce low energy secondary electrons. All the secondary electrons help ensure that the ionized cluster jet remains space charge neutral by providing low energy electrons that can be attracted into the positively ionized gas cluster jet as required to maintain space charge neutrality. Beam-forming electrodes 304a, 304b, and 304c are biased positively with respect to linear thermionic filaments 302a, 302b, and 302c and electron-repeller electrodes 306a, 306b, and 306c are negatively biased with respect to linear thermionic filaments 302a, 302b, and 302c. Insulators 308a, 308b, 308c, 308d, 308e, and 308f electrically insulate and support electrodes 304a, 304b, 304c, 306a, 306b, and 306c. For example, this self-neutralizing ionizer is effective and achieves over 1000 micro Amps argon GCIBs.

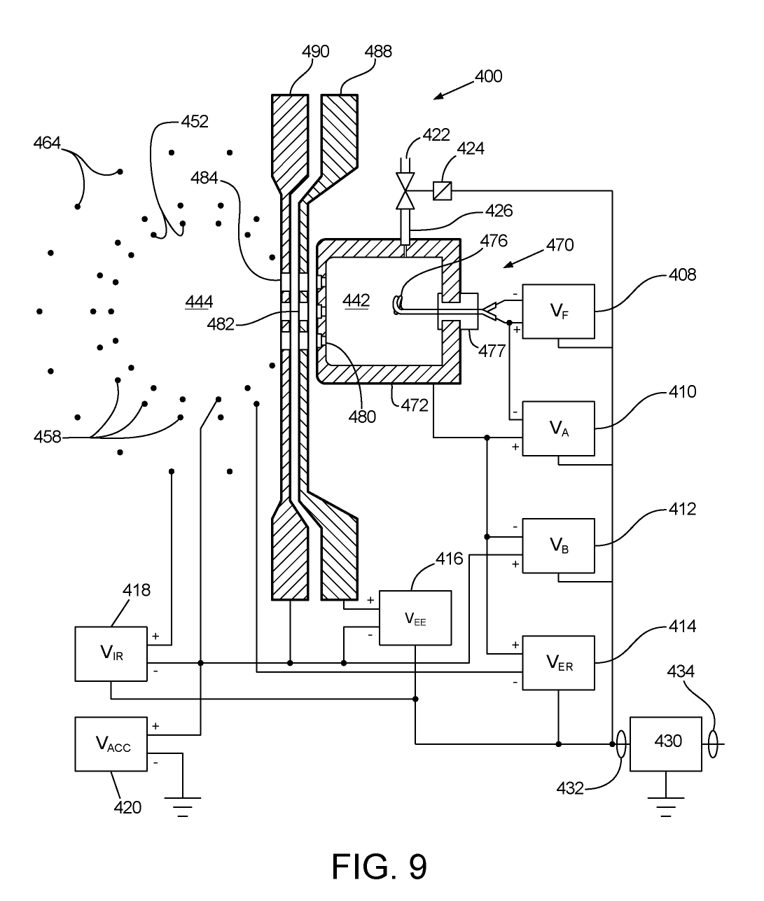

Alternatively, ionizers may use electron extraction from plasma to ionize clusters. The geometry of these ionizers is quite different from the three filament ionizer described above but the principles of operation and the ionizer control are very similar. Referring now to FIG. 9, a section 400 of a gas cluster ionizer (122, FIGS. 5, 6 and 7) for ionizing a gas cluster jet (gas cluster beam 118, FIGS. 5, 6 and 7) is shown. The section 400 is normal to the axis of GCIB 128. For typical gas cluster sizes (2000 to 15000 atoms), clusters leaving the skimmer aperture (120, FIGS. 5, 6 and 7) and entering an ionizer (122, FIGS. 5, 6 and 7) will travel with a kinetic energy of about 130 to 1000 electron volts (eV). At these low energies, any departure from space charge neutrality within the ionizer 122 will result in a rapid dispersion of the jet with a significant loss of beam current. FIG. 9 illustrates a self-neutralizing ionizer. As with other ionizers, gas clusters are ionized by electron impact.

The ionizer includes an array of thin rod anode electrodes 452 that is supported and electrically connected by a support plate (not shown). The array of thin rod anode electrodes 452 is substantially concentric with the axis of the gas cluster beam (e.g., gas cluster beam 118, FIGS. 5, 6 and 7). The ionizer also includes an array of thin rod electron-repeller rods 458 that is supported and electrically connected by another support plate (not shown). The array of thin rod electron-repeller electrodes 458 is substantially concentric with the axis of the gas cluster beam (e.g., gas cluster beam 118, FIGS. 5, 6 and 7). The ionizer further includes an array of thin rod ion-repeller rods 464 that is supported and electrically connected by yet another support plate (not shown). The array of thin rod ion-repeller electrodes 464 is substantially concentric with the axis of the gas cluster beam (e.g., gas cluster beam 118, FIGS. 5, 6 and 7).

Energetic electrons are supplied to a beam region 444 from a plasma electron source 470. The plasma electron source 470 comprises a plasma chamber 472 within which plasma is formed in plasma region 442. The plasma electron source 470 further comprises a thermionic filament 476, a gas entry aperture 426, and a plurality of extraction apertures 480. The thermionic filament 476 is insulated from the plasma chamber 470 via insulator 477. As an example, the thermionic filament 476 may include a tungsten filament having one-and-a-half turns in a “pigtail” configuration.

The section 400 of the gas cluster ionizer comprises an electron-acceleration electrode 488 having plural apertures 482. Additionally, the section 400 comprises an electron-deceleration electrode 490 having plural apertures 484. The plural apertures 482, the plural apertures 484, and the plural extraction apertures 480 are all aligned from the plasma region 442 to the beam region 444.

Plasma forming gas, such as a noble gas, is admitted to the plasma chamber 472 through gas entry aperture 426. An insulate gas feed line 422 provides pressurized plasma forming gas to a remotely controllable gas valve 424 that regulates the admission of plasma forming gas to the plasma chamber 472.

A filament power supply 408 provides filament voltage (VF) for driving current through thermionic filament 476 to stimulate thermo-electron emission. Filament power supply 408 controllably provides about 140 to 200 A (amps) at 3 to 5 V (volts). An arc power supply 410 controllably provides an arc voltage (VA) to bias the plasma chamber 472 positive with respect to the thermionic filament 476. Arc power supply 410 is typically operated at a fixed voltage, typically about 35 V, and provides means for accelerating the electrons within the plasma chamber 472 for forming plasma. The filament current is controlled to regulate the arc current supplied by the arc power supply 410. Arc power supply 410 is capable of providing up to 5 A arc current to the plasma arc.

Electron deceleration electrode 490 is biased positively with respect to the plasma chamber 472 by electron bias power supply 412. Electron bias power supply 412 provides bias voltage (VB) that is controllably adjustable over the range of from 30 to 400 V. Electron acceleration electrode 488 is biased positively with respect to electron deceleration electrode 490 by electron extraction power supply 416. Electron extraction power supply 416 provides electron extraction voltage (VEE) that is controllable in the range from 20 to 250 V. An acceleration power supply 420 supplies acceleration voltage (VACC) to bias the array of thin rod anode electrodes 452 and electron deceleration electrode 490 positive with respect to earth ground. VACC is the acceleration potential for gas cluster ions produced by the gas cluster ionizer shown in section 400 and is controllable and adjustable in the range from 1 to 100 kV. An electron repeller power supply 414 provides electron repeller bias voltage (VER) for biasing the array of thin rod electron-repeller electrodes 458 negative with respect to VACC. VER is controllable in the range of from 50 to 100 V. An ion repeller power supply 418 provides ion repeller bias voltage (VIR) to bias the array of thin rod ion-repeller electrodes 464 positive with respect to VACC. VIR is controllable in the range of from 50 to 150 V.

A fiber optics controller 430 receives electrical control signals on cable 434 and converts them to optical signals on control link 432 to control components operating at high potentials using signals from a grounded control system. The fiber optics control link 432 conveys control signals to remotely controllable gas valve 424, filament power supply 408, arc power supply 410, electron bias power supply 412, electron repeller power supply 414, electron extraction power supply 416, and ion repeller power supply 418.

For example, the ionizer design may be similar to the ionizer described in U.S. Pat. No. 7,173,252, entitled “Ionizer and method for gas-cluster ion-beam formation”; the content of which is incorporated herein by reference in its entirety.

The gas cluster ionizer (122, FIGS. 4, 5 and 6) may be configured to modify the beam energy distribution of GCIB 128 by altering the charge state of the GCIB 128. For example, the charge state may be modified by adjusting an electron flux, an electron energy, or an electron energy distribution for electrons utilized in electron collision-induced ionization of gas clusters.

Although only certain embodiments of this invention have been described in detail above, those skilled in the art will readily appreciate that many modifications are possible in the embodiments without materially departing from the novel teachings and advantages of this invention. Accordingly, all such modifications are intended to be included within the scope of this invention.

What is claimed is:

1. A method for preparing a memory device, comprising:
preparing a resistive switching layer between a pair of electrodes in a non-volatile memory element on a substrate, said resistive switching layer including a transition metal oxide, a transition metal nitride, a transition metal oxynitride, or a chalcogenide; and
programming a resistive switching property of said resistive switching layer to control a resistive switching behavior of said resistive switching layer using gas cluster ion beam (GCIB) processing by performing the following:
disposing said substrate in a GCIB processing system,
producing a GCIB in said GCIB processing system according to a process recipe containing one or more GCIB process parameters selected to achieve said resistive switching property, and
exposing said resistive switching layer to said GCIB.

2. The method of claim 1, wherein said resistive switching property includes a resistance for a low resistance state, a resistance for a high resistance state, or a resistance range between a low resistance state and a high resistance state for the resistive switching behavior of said resistive switching layer.

3. The method of claim 1, wherein said resistive switching layer includes a heating layer in a phase-change random access memory (PCRAM) device, wherein said heating layer switches resistive states by Joule heating.

4. The method of claim 1, wherein said resistive switching property includes one or more properties selected from the group consisting of resistivity and temperature coefficient of resistivity.

5. The method of claim 1, wherein said resistive switching layer includes an ion conductor layer in a resistive-switching random-access memory (ReRAM) device, and wherein at least one of said pair of electrodes serves as a source of metal ions to said ion conductor layer.

6. The method of claim 1, wherein said resistive switching property includes a susceptibility for defect formation in said resistive switching layer, said susceptibility for defect formation affects conductive path formation when switching between resistance states.

7. The method of claim 1, wherein said resistive switching property includes a susceptibility for conductive precipitation in said resistive switching layer, said susceptibility for conductive precipitation affects conductive bridge formation when switching between resistance states.

8. The method of claim 1, wherein said resistive switching layer includes an element selected from the group consisting of Ge, Si, Cu, Ag, Ni, Ti, W, Hf, and V.

9. The method of claim 1, wherein said GCIB is configured to modify a chemical composition of said resistive switching layer.

10. The method of claim 1, wherein said GCIB contains O, N, S, Se, Te, Si, Ge, He, Ne, Ar, Kr, or Xe, or any combination of two or more thereof.

11. The method of claim 1, wherein said GCIB is configured to remove impurities from said resistive switching layer.

12. The method of claim 1, wherein said GCIB is configured to alter a thickness of said resistive switching layer by etching material from said resistive switching layer, growing material on said resistive switching layer, or depositing material on said resistive switching layer.

13. The method of claim 1, wherein said GCIB is configured to amorphize said resistive switching layer, or alter a crystallinity of said resistive switching layer.

14. The method of claim 1, wherein said GCIB is configured to alter an interfacial roughness between said resistive switching layer and at least one of said pair of electrodes.

15. The method of claim 1, further comprising:
adjusting a spatial variation of said resistive switching property for said resistive switching layer across said substrate using said GCIB.

16. The method of claim 15, wherein said adjusting includes spatially tuning said resistive property uniformly across said substrate.

17. The method of claim 15, wherein said adjusting includes spatially tuning said resistive property differentially across said substrate.

18. The method of claim 1, further comprising:
producing another GCIB in said GCIB processing system to process at least one of said pair of electrodes.

19. A method of preparing a non-volatile memory device, comprising:
preparing a non-volatile memory device on a substrate, said non-volatile memory device including a resistive-switching random-access memory (ReRAM) device; and
treating at least one layer in said non-volatile memory device using a gas cluster ion beam (GCIB) to perform at least one of smoothing a surface of said at least one layer, roughening a surface of said at least one layer, etching said at least one layer, growing material on said at least one layer, depositing material on said at least one layer, modifying a composition said at least one layer, amorphizing said at least one layer, or changing a crystallinity of said at least one layer, or any combination of two or more thereof.

20. The method of claim 19, wherein said non-volatile memory device includes a phase-change random access memory (PCRAM) device or a conductive-bridging random-access memory (CBRAM) device.
